(19) United States
(12) Patent Application Publication
(10) Pub. No.: US 2008/0088555 A1
(43) Pub. Date: Apr. 17, 2008

(54) GATE DRIVING CIRCUIT AND DISPLAY APPARATUS HAVING THE SAME

(76) Inventors: Ae Shin, Suwon-si (KR); Jin Jeon, Suwon-si (KR); Kee-Han Uh, Yongin-si (KR); Jin-Young Choi, Seoul (KR)

Correspondence Address: F. CHAU & ASSOCIATES, LLC, 130 WOODBURY ROAD, WOODBURY, NY, 11797, US

(21) Appl. No.: 11/870,041

(22) Filed: Oct. 10, 2007

(30) Foreign Application Priority Data
Oct. 12, 2006 (KR) 2006-99119

(51) Int. Cl. G09G 3/36; H03K 3/00

(52) U.S. Cl. 345/87; 327/112; 345/98

(57) ABSTRACT

A gate driving circuit includes a shift resister having stages cascade-connected to one another. Each stage includes a pull-up part, a first pull-up driving part, a first pull-down part and a first ripple prevention part. The pull-up part outputs a high value of a first clock signal to a first output terminal. The first pull-up driving part applies a low value to a control electrode of the pull-up part to turn off the pull-up part. The first pull-down part applies the low value to the signal outputted to the first output terminal. The first ripple prevention part applies the low value of the first input signal to the control electrode of the pull-up part to turn off the pull-up part, and prevents ripple from occurring at the control electrode of the pull-up part. Thus, an abnormal gate-on signal is prevented, to reduce driving malfunction of a display apparatus.

This application claims priority under 35 U.S.C. §119 to Korean Patent Application No. 2006-99119, filed on Oct. 12, 2006, in the Korean Intellectual Property Office (KIPO), the contents of which in its entirety are herein incorporated by reference in their entirety.

### BACKGROUND OF THE INVENTION

1. Technical Field

The present disclosure relates to a gate driving circuit and a display apparatus having the gate driving circuit. More particularly, the present disclosure relates to a gate driving circuit capable of decreasing driving malfunctions and a display apparatus having the gate driving circuit.

2. Discussion of Related Art

Generally, a liquid crystal display (“LCD”) apparatus includes an array substrate, a counter substrate facing the array substrate, and a liquid crystal layer including liquid crystal molecules having an anisotropic dielectric ratio. When an electric field is applied to the liquid crystal layer, light transmissivity is controlled by an intensity of the electric field. Thus, an image is displayed.

The LCD apparatus includes a display panel, a gate driving part and a data driving part. The display panel includes gate lines, data lines arranged so that the longitudinal direction of which crosses that of the gate lines, and a plurality of pixel portions defined by the crossing gate and data lines. The gate driving part outputs a gate signal to the gate lines. The data driving part outputs a data signal to the data lines. Generally, the gate and data driving parts are formed as chips mounted on the display panel.

Recently, the gate driving part has been integrated on the display substrate in the form of an integrated circuit, to reduce the overall size of the LCD apparatus and to enhance productivity. Noise malfunctions in which an abnormal gate-on signal occurs in a gate-off signal section, however, are caused in the gate driving part integrated on the display substrate like the integrated circuit.

More specifically, a coupling with a clock signal due to a parasitic capacitance of a pull-up element increases an off-voltage of a gate electrode, and at the same time a leakage current is increased according to an increase in temperature, so that the pull-up element is turned on. Thus, the gate-on signal intermittently occurs in the gate-off signal section, so that the display error is caused.

### BRIEF SUMMARY OF THE INVENTION

Exemplary embodiments of the present invention provide a gate driving circuit for decreasing driving malfunctions of a display apparatus.

Exemplary embodiments of the present invention also provide a display apparatus having the gate driving circuit.

In a gate driving circuit according to an exemplary embodiment of the present invention, the gate driving circuit may include a shift register having a plurality of stages cascade-connected to one another. Each of the stages may include a pull-up part, a first pull-up driving part, a first pull-down part and a first ripple prevention part. The pull-up part outputs a high value of a first clock signal to a first output terminal, in response to a high value of a first input signal. The first pull-up driving part applies a low value to a control electrode of the pull-up part, in response to a high value of a second input signal, to turn off the pull-up part. The first pull-down part applies the low value to the signal outputted to the first output terminal, in response to a high value of a second clock signal. The first ripple prevention part applies the low value of the first input signal to the control electrode of the pull-up part in response to the high value of the second clock signal to turn off the pull-up part, and prevents ripple from occurring at the control electrode of the pull-up part.

In a display apparatus according to an exemplary embodiment of the present invention, the display apparatus may include a display panel, a data driving circuit, and a gate driving circuit. The display panel may include a display area having a plurality of pixel portions defined by gate lines and data lines, and a peripheral area disposed to is enclose the display area. The data driving circuit outputs a data signal to the data lines. The gate driving circuit is formed in the peripheral area and may include a plurality of stages cascade-connected to one another, for outputting a gate signal to the gate lines. Each of the stages of the gate driving circuit may include a pull-up part, a first pull-up driving part, a first pull-down part and a first ripple prevention part. The pull-up part outputs a high value of a first clock signal to a first output terminal, in response to a high value of a first input signal. The first pull-up driving part applies a low value to a control electrode of the pull-up part, in response to a high value of a second input signal. The first pull-down part applies the low value to the signal outputted to the first output terminal, in response to a high value of a second clock signal. The first ripple prevention part applies the low value of the first input signal to the control electrode of the pull-up part in response to the high value of the second clock signal to turn off the pull-up part, and prevents ripple from occurring at the control electrode of the pull-up part.

According to an exemplary embodiment of the present invention, the low value of the control electrode of the pull-up part (for example, an off-voltage) is safely maintained, so that the ripple caused by the coupling of the clock signal is improved. Thus, an abnormal gate-on signal in the gate-off signal section is prevented, to reduce the driving malfunction of the display apparatus.

### BRIEF DESCRIPTION OF THE DRAWINGS

Exemplary embodiments of the present invention will be understood in more detail from the following descriptions taken in conjunction with the accompanying drawings, in which:

FIG. 1 is a plan view illustrating a display apparatus according to an exemplary embodiment of the present invention;

FIG. 2 is a block diagram illustrating a driving part of the apparatus shown in FIG. 1;

FIG. 3 is a block diagram illustrating a gate driving circuit in FIG. 1 according to an exemplary embodiment of the present invention;

FIG. 4 is a circuit diagram illustrating a stage of the circuit shown in FIG. 3;

FIG. 5 is a waveform diagram illustrating a driving operation of the stage shown in FIG. 4;

FIG. 6 is a block diagram illustrating the gate driving circuit shown in FIG. 1 according to an exemplary embodiment of the present invention;

FIG. 7 is a circuit diagram illustrating a stage shown in FIG. 6; and

FIG. 8 is a waveform diagram illustrating a driving operation of the stage shown in FIG. 7.

### DESCRIPTION OF THE EXEMPLARY EMBODIMENTS

The present invention is described more fully hereinafter with reference to the accompanying drawings, in which exemplary embodiments of the present invention are shown. This invention may, however, be embodied in many different forms and should not be construed as limited to the exemplary embodiments set forth herein. Rather, these embodiments are provided so that this disclosure will be thorough and complete, and will fully convey the scope of the present invention to those skilled in the art.

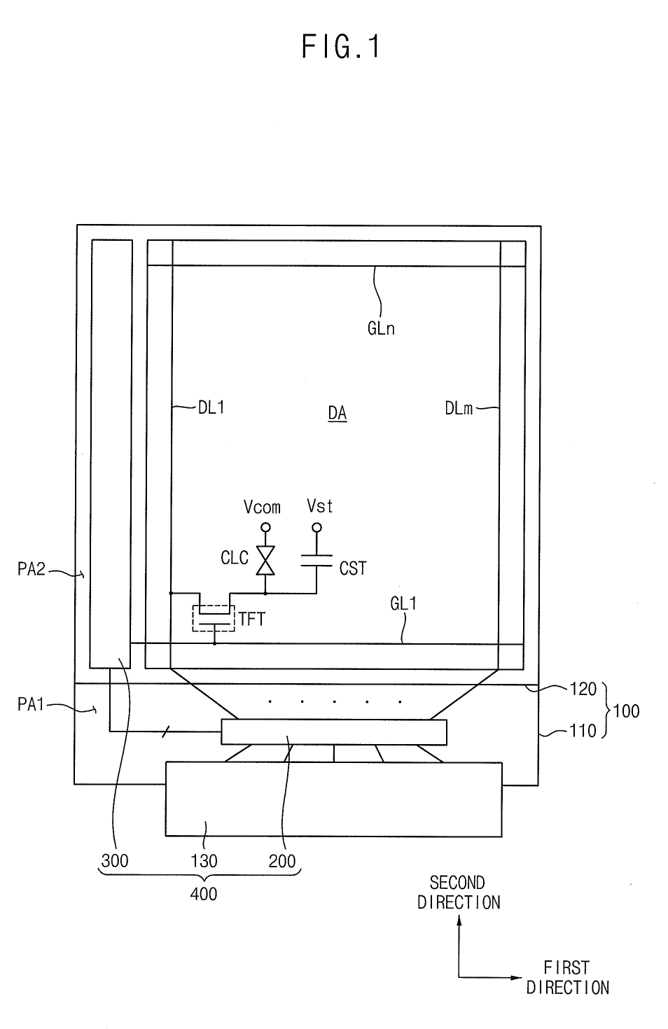

FIG. 1 is a plan view illustrating a display apparatus according to an exemplary embodiment of the present invention.

Referring to FIG. 1, the display apparatus may include a display panel 100, and a driving circuit part 400 for driving the display panel 100.

The display panel 100 may include an array substrate 110, a counter substrate (for example, a color filter substrate) combined with the array substrate 110, and a liquid crystal layer (not shown) disposed between the array substrate 110 and the counter substrate 120. The display panel 100 may include a display area DA displaying an image, and a peripheral area PA1 and PA2 surrounding the display area DA. The peripheral area may include a first peripheral area PA1 disposed at an end portion of data lines DL1˜DLm, and a second peripheral area PA2 disposed at an end portion of gate lines GL1˜GLn, where m and n are natural numbers.

A plurality of gate lines GL1˜GLn is formed along a first direction in the display area DA. A plurality of data lines DL1˜DLm is formed along a second direction crossing the first direction in the display area DA. A plurality of pixel portions is defined by the plurality of gate lines GL1˜GLn and the plurality of data lines DL1˜DLm. A thin film transistor TFT, a liquid crystal capacitor CLC and a storage capacitor CST are formed in each pixel portion. The thin film transistor TFT is electrically connected to the gate line GL and the data line DL. The liquid crystal capacitor CLC and the storage capacitor CST are electrically connected to the thin film transistor TFT.

The driving circuit 400 may include a driving part 200, a gate driving circuit 300 and a flexible circuit board 130.

The driving part 200 may be formed as a single chip and is mounted on the first peripheral area PA1. The driving part 200 applies a gate control signal to the gate driving part 130, and outputs a data voltage to the data lines DL1˜DLm.

The gate driving circuit 300 is integrated on the second peripheral area PA2 that is disposed at the end portion of the gate lines GL1˜GLn. The gate driving circuit 300 sequentially outputs a gate signal that activates the gate lines GL1˜GLn, based oil the gate control signal applied from the driving part 200.

The flexible circuit board 130 is attached to the first peripheral area PA1 of the display panel 200 and electrically connects an external device with the driving part 200 to transfer an original data signal and synchronized signals that are applied from an external device (not shown) to the driving part 200.

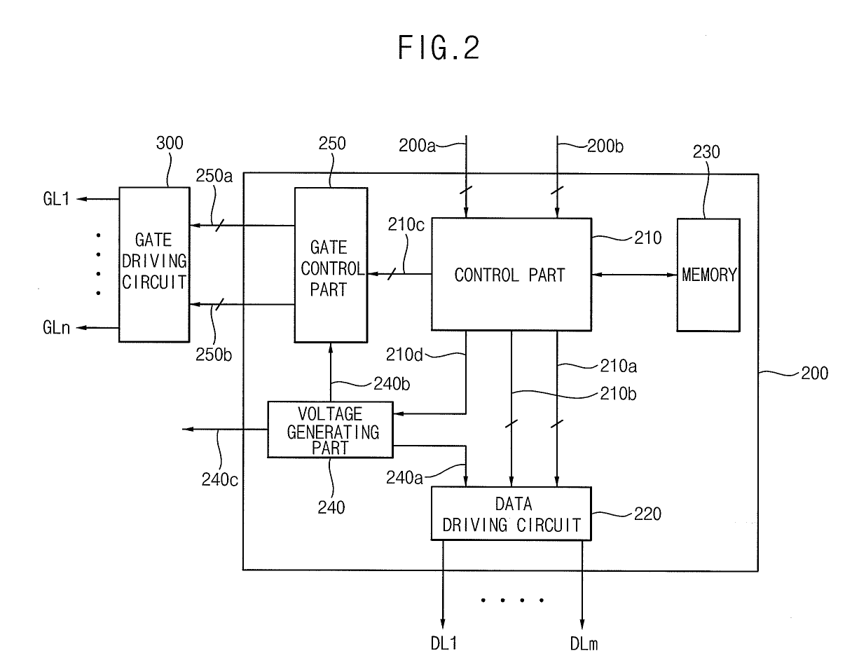

FIG. 2 is a block diagram illustrating a driving part in FIG. 1.

Referring to FIGS. 1 and 2, the driving part 200 may include a control part 210, a data driving circuit 220, a memory 230, a voltage generating part 240, and a gate control part 250.

The control part 210 receives the original data signal 200a and the synchronized signals 200b from the external device. The synchronized signals 200b may include a vertical synchronized signal, a horizontal synchronized signal, a main clock signal, and a data enable signal. The control part 210 stores the original data signal 200a to the memory 230 and reads the original data signal 200a from the memory 230 based on the received synchronized signals 200b. The control part 210 provides a data signal 210a corresponding to the original data signal 200a read from the memory 230 to the data driving circuit 220. For example, the data signal 210a provided to the data driving circuit 220 may be a digital signal.

In addition, the control part 210 generates a first control signal 210b (for example, a data control signal), a second control signal 210c (for example, a gate control signal) and a third control signal 210d, based on the synchronized signals 200b. The first control signal 210b is provided to the data driving circuit 220, the second control signal 210c is provided to the gate control part 250, and the third control signal 210d is provided to the voltage generating part 240.

The memory 230 stores the original data signal 200a provided by the control part 210 in predetermined units. For example, the memory 230 stores the original data signal 200a by a frame unit, a field unit, or a line unit.

The voltage generating part 240 is controlled by the third control signal 210d provided by the control part 210, so that the voltage generating part 240 generates various voltages for driving the display panel 100. The driving voltages are generated by using an external power supply, and include a gamma reference voltage 240a, a gate voltage 240b, and a common voltage 240c. The gamma reference voltage 240a is provided to the data driving circuit 220, the gate voltage 240b is provided to the gate control part 250, and the common voltage 240c is provided to a common electrode (not shown) of the liquid crystal capacitor CLC.

The data driving circuit 220 receives the first control signal 210b and the data signal 210a from the control part 210, converts the data signal 210b having the digital signal into the data voltage having an analog signal corresponding to the data signal 210b, and outputs the data voltage to the data lines DL1˜DLm. In this case, the first control signal 210b may include the horizontal start signal, a load signal and a reversed signal. The data voltage is selected from among divided voltage levels to display each gray scale, based on the gamma reference voltage 240a provided by the voltage generating part 240.

The gate control part 250 provides the second control signal 210c provided by the control part 210 and the gate voltage 240b provided by the voltage generating part 240 to the gate driving part 300. In this exemplary embodiment, the second control signal 210c may include the vertical start signal, a first clock signal and a second clock signal. The first and second clock signals have different phases and are reversed by every 1H period. The 1H is one horizontal section equal to one horizontal scan time. The gate voltage 240b may include an off-voltage.

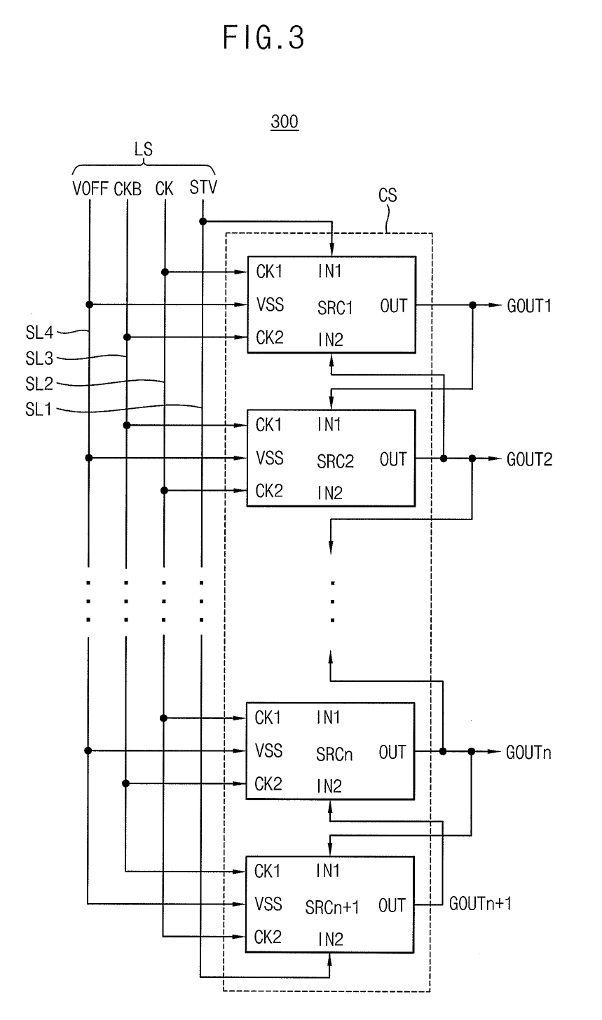

FIG. 3 is a block diagram illustrating a gate driving circuit in FIG. 1 according to an exemplary embodiment of the present invention.

Referring to FIGS. 1 to 3, the gate driving circuit 300 may include a circuit part CS and a line part LS. The circuit part CS may include a first stage to an (n+1)-th stage, SRC1˜SRCn+1, that are cascade-connected to one another, and sequentially outputs the gate signal GOUT. The line part LS provides various control signals and driving voltages to the circuit part CS.

The first to (n+1)-th stages SRC1˜SRCn+1 of the circuit part CS may include n numbers of driving stages SRC1˜SRCn that respectively correspond to the gate lines GL1˜GLn, and one dummy stage SRCn+1. Each of the stage SRC1˜SRCn+1 may include a first clock terminal CK1, a second clock terminal CK2, a first input terminal and a second input terminal IN2, a voltage terminal VSS and a first output terminal OUT.

In the k-th stage SRCk, wherein k is a natural number between 1 to n+1, the first and second clock signals CK and CKB that are reversed by the 1H period and have the phases reversed relative to each other are respectively inputted to the first and second clock terminals CK1 and CK2.

For example, in the odd-numbered stages SRC1, SRC3, . . . , the first clock signal CK is inputted to the first clock terminal CK1, and the second clock signal CKB having the phase reversed relative to the first clock signal CK is inputted to the second clock terminal CK2. In the even-numbered stages SRC2, SRC4, . . . , however, the second clock signal CKB is inputted to the first clock terminal CK1, and the first clock signal CK having the phase reversed relative to the second clock signal CKB is inputted to the second clock terminal CK2. For example, the first and second clock signals CK and CKB are inputted reversed to the odd-numbered stages SRC1, SRC2, . . . , and the even-numbered stages SRC2, SRC4, . . . .

The vertical start signal STV or the gate signal GOUTk−1 of the (k−1)-th stage SRCk−1 is inputted to the first input terminal IN1 of the k-th stage SRCk. For example, the vertical start signal STV is inputted to the first input terminal IN1 of the first stage SRC1, and the gate signals GOUT1˜GOUTn of the first to n-th stages SRC1˜SRCn are respectively inputted to the first input terminals IN1 of the second to (n+1)-th stages SRC2˜SRCn+1. The gate signal GOUT may be defined as the signal outputted to the first output signal OUT of each stage.

The gate signal GOUTk+1 of the (k+1)-th stage SRCk+1 or the vertical start signal STV is inputted to the second input terminal IN2 of the k-th stage SRCk. For example, the gate signals GOUT2˜GOUTn+1 of the second to (n+1)-th stages SRC2˜SRCn+1 are respectively inputted to the second input terminals IN2 of the first to n-th stages SRC1˜SRCn, and the vertical start signal STV is inputted to the second input terminal IN2 of the (n+1)-th stage SRCn+1.

The off-voltage is inputted to the voltage terminal VSS of the k-th stage SRCk. The off-voltage is inputted to each voltage terminal VSS of the first to (n+1)-th stages SRC1˜SRCn+1.

A high section of the first clock signal CK or the second clock signal CKB provided to the first clock terminal CK1 is outputted through the first output terminal OUT of the k-th stage SRCk, and defines a gate-on signal. For example, in the odd-numbered stages SRC1, SRC3, . . . , the high section of the first clock signal CK is outputted through the first output terminal OUT. In the even-numbered stages SRC2, SRC4, . . . , the high section of the second clock signal CKB is outputted through the first output terminal OUT. When the gate-on signal is not applied, the signal outputted through the first output terminal OUT is converted into the off-voltage VOFF, to define a gate-off signal.

The line part LS may include a plurality of signal lines at an edge of the circuit part CS of the gate driving circuit 300 and acts to transfer the control signal and the driving voltage of the first to (n+1)-th stages SRC1˜SRCn+1.

The line part LS may include a start signal line SL1, a first clock line SL2, a second clock line SL3 and a voltage line SL4.

The start signal line SL1 receives the vertical start signal STV from the driving part 300, and provides the vertical start signal STV to the first input terminal IN1 of the first stage SRC1 and the second input terminal IN2 of the final stage SRCn+1.

The first clock line SL2 receives the first clock signal CK that is reversed by the 1H period from the driving part 300, and provides the first clock signal CK to the first clock terminals CK1 of the odd-numbered stages SRC1, SRC3, . . . and the second clock terminals CK2 of the even-numbered stages SRC2, SRC4, . . . .

The second clock line SL3 receives the second clock signal CKB having the phase reversed relative to the first clock signal CK from the driving part 300, and provides the second clock signal CKB to the second clock terminals CK2 of the odd-numbered stages SRC1, SRC3, . . . and the first clock terminals CK1 of the even-numbered stages SRC2, SRC4, . . . .

The voltage line SL4 receives the off-voltage VOFF from the driving part 300, and provides the off-voltage VOFF to each voltage terminal VSS of the first to (n+1)-th stages SRC1˜SRCn+1.

In the gate driving circuit 300 mentioned above, the gate signal GOUTk−1 of the (k−1)-th stage SRCk−1 is inputted through the first input terminal IN1, and the gate signal GOUTk+1 of the (k+1)-th stage SRCk+1 is inputted through the second input terminal IN2, so that the gate driving circuit 300 is driven. Alternatively, the gate signals GOUTk−2, GOUTk−3, . . . of the (k−2)-th, (k−3)-th, . . . stages SRCk−2, SRCk−3, . . . may be inputted through the first input terminal IN1, and the gate signals GOUTk+2, GOUTk+3, . . . of the (k+2)-th, (K+3)-th, . . . stages SRCk+2, SRCk+3 may be inputted through the second input terminal IN2, so that the gate driving circuit 300 may be driven.

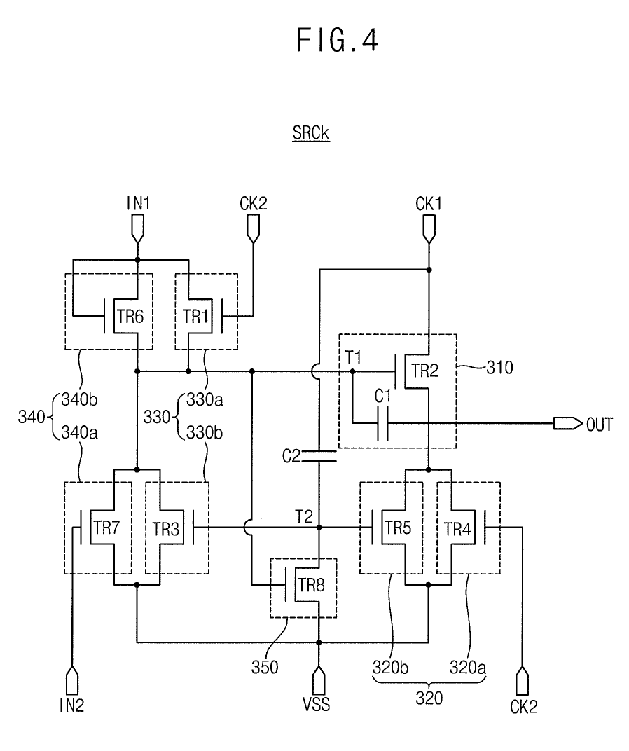

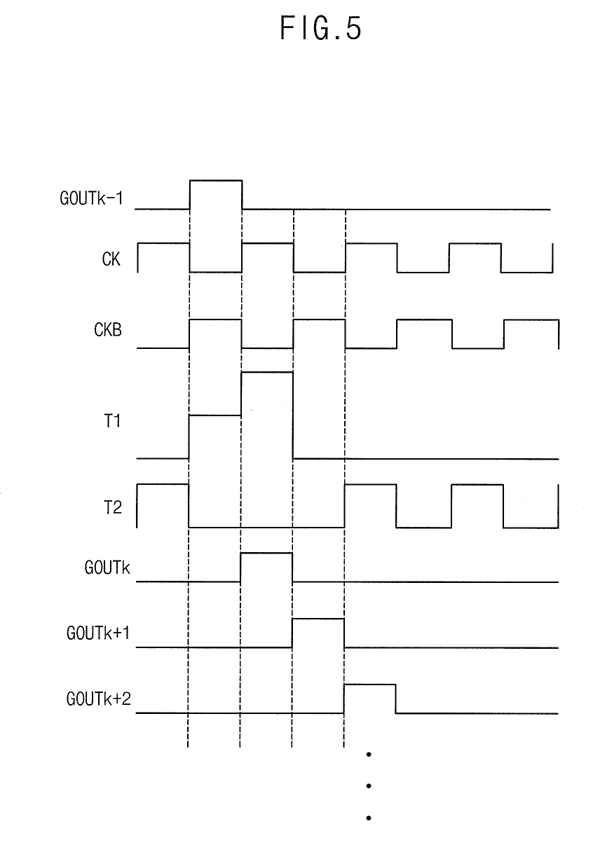

FIG. 4 is a circuit diagram illustrating a stage in FIG. 3. FIG. 5 is a waveform diagram illustrating a driving operation of the stage in FIG. 4.

For the convenience of explanation, the k-th stage SRCk, which is an odd-numbered stage that has the first clock signal CK provided to the first clock terminal CK1 and the second clock signal CKB provided to the second clock terminal CK2, will be explained as an exemplary embodiment.

Referring to FIGS. 4 and 5, the k-th stage SRCk of the gate driving circuit 300 may include a pull-up part 310 and a pull-down part 320.

The pull-up part 310 outputs the high section of the first clock signal CK to the first output terminal OUT, to pull up the k-th gate signal GOUTk. The pull-down part 320 may include a first pull-down part 320a and a second pull-down part 320b. The first pull-down part 320a converts the signal outputted to the first output terminal OUT in response to the second clock signal CKB into the off-voltage VOFF (low value), to pull down the signal. The second pull-down part 320b maintains the signal outputted to the first output terminal OUT in response to the first clock signal CK to be in the off-voltage VOFF, to pull down the signal. In this case, the first clock signal CK that turns the second pull-down part 320b on is the first clock signal CK charged to a switching capacitor C2, which will be explained in the following.

The pull-up part 310 may include a second switching element TR2 having an input electrode, an output electrode, and a control electrode. The input electrode is electrically connected to the first clock terminal CK1 to receive the first clock signal CK. The output electrode is electrically connected to the first output terminal OUT. The control electrode is electrically connected to the first input terminal to receive the first input signal. In this case, the first input signal is the (k−1)-th gate signal GOUTk−1 of the (k−1)-th stage SRCk−1 that is inputted through the first input terminal IN1. The first input signal is the vertical start signal STV in the first stage SRC1. The gate signal is GOUT is defined as the signal outputted to the first output terminal OUT.

The pull-up part 310 may further include a charging capacitor C1 that is formed between the control and output electrodes of the second switching element TR2. The charging capacitor C1 stores the first input signal applied to the control electrode of the second switching element TR2, to turn the second switching element TR2 on. The charging capacitor C1 may be defined by an overlapped area between die control and the output electrodes of the second switching elements TR2.

The first pull-down part 320a may include a fourth switching element TR4 having an input electrode, a control electrode and an output electrode. Tile input electrode is electrically connected to the voltage terminal VSS to receive the off-voltage VOFF. The control electrode is electrically connected to the second clock terminal CK2 to receive the second clock terminal CKB. The output electrode is electrically connected to the first output terminal OUT.

The second pull-down part 320b may include a fifth switching element TR5 having an input electrode, a control electrode and an output electrode. The input electrode is electrically connected to the voltage terminal VSS to receive the off-voltage VOFF. The control electrode is electrically connected to the switching capacitor C2 to receive the first clock signal CK. The output electrode is electrically connected to the first output terminal OUT.

The k-th stage SRCk may further include a pull-up driving part 340. The pull-up driving part 340 turns on the pull-up part 310, in response to the high value of the first input signal, and turns off the pull-up part 310, in response to the high value of the second input signal.

For the convenience of explanation, the first input signal is the (k−1)-th gate signal GOUTk−1 of the (k−1)-th stage SRCk−1 and the second input signal is the (k+1)-th gate signal GOUTk+1 of the (k+1)-th stage SRCk+1.

The pull-up driving part 340 may include a first pull-up driving part 340a and a second pull-up driving part 340b.

The first pull-up driving part 340a may include a seventh switching element TR7 having an input electrode, an output electrode, and a control electrode. The input electrode is electrically connected to the voltage terminal VSS to receive the off-voltage VOFF. The output terminal is electrically connected to the control electrode of the second switching element TR2 to form a first node T1. The control electrode receives the second input signal. In this exemplary embodiment, the second input signal is the (k+1)-th gate signal GOUTk+1 of the (k+1)-th stage SRCK+1 inputted to the second input terminal IN2, and is the vertical start signal STV in the final stage.

The second pull-up driving part 340b may include a sixth switching element TR6 having an input electrode, a control electrode, and an output electrode. The input and control electrodes are electrically connected to the first input terminal IN1 in common to receive the (k−1)-th gate signal GOUTk−1. The output electrode is electrically connected to the control electrode of the switching element TR2 to form the first node T1. The control electrode of the second switching element TR2 may be defined as the control electrode of the pull-up part 310.

When the sixth switching element TR6 is turned on in response to the high value of the (k−1)-th gate signal GOUTk−1 in the pull-up driving part 340, the high value of the (k−1)-th gate signal GOUTk−1 is applied to the first node T1 to be charged to the charging capacitor C1. An electrical discharge over a threshold voltage is charged to the charging capacitor C1, the first clock signal CK having the low value is reversed to have the high value, and the second switching element TR2 becomes a bootstrap, so that the high value of the first clock signal CK is outputted to the first output terminal OUT.

For example, the high value of the (k−1)-th gate signal GOUTk−1 is inputted, the first clock signal CK having the low value is reversed to the first clock signal CK having the high value, and the second switching element TR2 becomes a bootstrap, so that the gate-on signal of the k-th gate signal GOUTk is outputted to the first output terminal OUT. Then, when the seventh switching element TR7 is turned on in response to the high value of the (k+1)-th gate signal GOUTk+1, the electrical discharge charged to the charging capacitor C1 is discharged to the off-voltage VOFF of the voltage terminal VSS. After the charging capacitor C1 is discharged, the first node T1 is converted to the low value and the second switching element TR2 is turned off, so that the output of the first clock signal CK is stopped.

When the fourth switching element TR4 is turned on in response to the high value of the second clock signal CKB with the turn-off of the second switching element TR2, the signal outputted to the first output terminal OUT is converted to the off-voltage VOFF (hereinafter, referred to as a low value) so that the gate-off signal of the k-th gate signal GOUTk is outputted. In addition, a fifth switching element TR5 is turned on in response to the high value of the first clock signal CK charged to the switching capacitor C2, and the signal outputted to the first output terminal OUT is maintained at the low value. For example, the fourth switching element TR4 and the fifth switching element TR5 are sequentially turned on, so that the signal outputted to the first output terminal OUT is pulled down to the low value.

The k-th stage SRCk may further include a ripple prevention part 330. The ripple prevention part 330 maintains the first node T1 to be the off-voltage VOFF, so that it prevents a ripple of the first node T1 that is generated by a coupling of die first clock signal CK.

The ripple prevention part 330 may include a first ripple prevention part 330a and a second ripple prevention part 330b.

The first ripple prevention part 330a may include a first switching element TR1 having an input electrode, an output electrode, and a control electrode. The input electrode is electrically connected to the first input terminal IN1 to receive the (k−1)-th gate signal GOUTk−1. The output electrode is electrically connected to the first node T1. The control electrode is electrically connected to the second clock terminal CK2 to receive the second clock signal CKB.

The second ripple prevention part 330b may include a third switching element TR3 having an input electrode, a control electrode, and an output electrode. The input electrode is electrically connected to the voltage terminal VSS to receive the off-voltage VOFF. The control electrode is electrically connected to the switching capacitor C2 to receive the first clock signal CK. The output electrode is electrically connected to the first node T1.

After the k-th gate signal GOUTk is converted to the low value by the pull-down part 320, the ripple prevention part 330 maintains the first node T1 to have the low value to maintain the pull-up part 310 to be turned off. In addition, the low value of the first node T1 is safely maintained, so that the ripple generated at the first node T1 is prevented by the coupling due to the first clock signal CK. The ripple of the first node T1 is generated by a parasitic capacitance between the input electrode and the control electrode of the second switching element TR2.

When the first switching element TR1 is turned on in response to the high value of the second clock signal CKB, the ripple prevention part 330 applies the low value of the (k−1)-th gate signal GOUTk−1 to the first node T1. Thus, the first node T1 that has already been converted to the low value by the first pull-up driving part 340a, is maintained at the low value. In addition, when the third switching element TR3 is turned on in response to the high value of the first clock signal CK charged to the switching capacitor C2, the off-voltage VOFF of the voltage terminal VSS is applied to the first node T1, so that the first node T1 is maintained at the low value.

The first switching element TR1 and the third switching element TR3 are sequentially turned on by the 1H period to maintain the first node T1 at the low value. Thus, the ripple generated at the first node T1 may be prevented.

When the (k−1)-th gate signal GOUTk−1 is the high value, the ripple prevention part 330 including the first switching element TR1 has the same function as the sixth switching element TR6. Thus, the charge of the charging capacitor C1 due to the high value of the (k−1)-th gate signal GOUTk−1 is improved, so that driving characteristics may be enhanced.

The k-th stage SRCk may further include the switching capacitor C2 and a pull-down control part 350. The switching capacitor C2 transfers the first clock signal CK inputted to the switching capacitor C2 to turn on the second ripple prevention part 330b and the second pull-down part 320b. The pull-down control part 350 turns the second ripple prevention part 330b and the second pull-down part 320b off, in response to the first node T1 (for example, the control electrode of the pull-up part) signal.

The switching capacitor C2 may include a first electrode and a second electrode. The first electrode is electrically connected to the first clock terminal CK1 to receive the first clock signal CK. The second electrode is electrically connected to the control electrodes of the third and fifth switching elements TR3 and TR5 to become a second node T2. The switching capacitor C2 receives and stores the first clock signal CK, and applies the stored first clock signal CK to the second node T2 to turn on or off the third switching element TR3 and the fifth switching element TR5.

The pull-down control part 350 may include an eighth switching element TR8 having an input electrode, an output electrode, and a control electrode. The input electrode is electrically connected to the voltage terminal VSS to receive the off-voltage VOFF. The output electrode is electrically connected to the second node T2. The control electrode is electrically connected to the first node T1. The pull-down control part 350 converts the second node T2 to the low value, in response to the first node T1 signal. For example, when the high value of the first clock signal CK is applied to the second node T2 through the switching capacitance C2, and the first node T1 signal is the high value, the eighth switching element TR8 is turned on to convert the second node T2 to the low value. Thus, the second ripple prevention part 330b and the second pull-down part 320b are turned off regardless of the first clock signal CK, in the section where the first node T1 is the high value to maintain the pull-up part 310 to be turned on.

In the gate driving circuit 300 according to the exemplary embodiment, the first ripple prevention part 330a and the second tipple prevention part 330b maintain the low value of the first node T1, respectively, in response to the second clock signal CKB and the first clock signal CK, so that the ripple may be prevented.

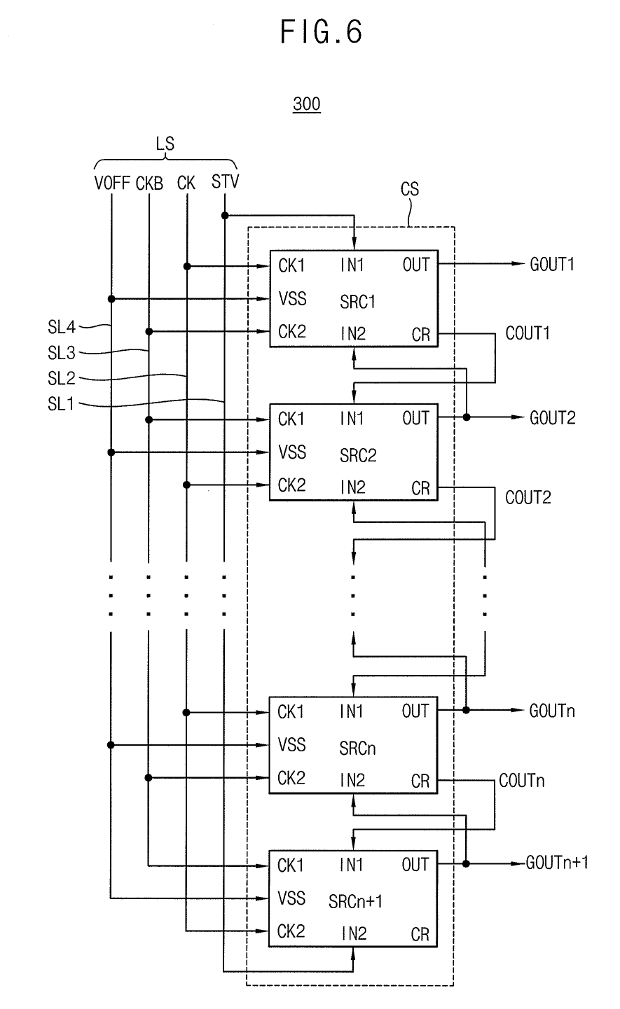

FIG. 6 is a block diagram illustrating the gate driving circuit in FIG. 1 according to an exemplary embodiment of the present invention.

The gate driving circuit of the exemplary embodiment of FIG. 6 is almost the same as in the exemplary embodiment of FIG. 3. Thus, the same reference numerals will be used to refer to the same or like parts as those described in the exemplary embodiment of FIG. 3 and any further repetitive explanation concerning the above elements will be omitted.

Referring to FIGS. 1, 2 and 6, the gate driving circuit 300 may include a circuit part CS and a line part LS.

The circuit part CS may include a first stage to an (n+1)-th stage SRC1˜SRCn+1 that are cascade-connected to one another. Each stage corresponds to each gate line GL1˜GLn one by one, and sequentially outputs a gate signal GOUT. The line part LS is formed at one side of the circuit part CS, and provides a control signal and a driving voltage to the circuit part CS.

Each of the first to (n+1)-th stages SRC1˜SRCn+1 may include a first clock terminal CK1, a second clock terminal CK2, a first input terminal IN1, a second input terminal IN2, a voltage terminal VSS, a first output terminal OUT, and a second output terminal CR.

The first clock signal CK and the second clock signal CKB that are reversed every 1H period and have phases reversed relative to each other, are respectively inputted to the first clock terminal CK1 and the second clock terminal CK2 of the k-th stage SRCk. In this exemplary embodiment, the first clock signal CK is inputted to odd-numbered stages SRC1, SRC3, . . . , and in reverse the second clock signal CKB is inputted to even-numbered stages SRC2, SRC4, . . . .

A vertical start signal STV or a carry signal COUTk−1 of the (k−1)-th stage SRCk−1 is inputted to the first input terminal IN1. For example, the vertical start signal STV is inputted to the first input terminal IN1 of the first stage SRC1, and the (k−1)-th carry signal COUTk−1 is inputted to the first input terminal IN1 of the second to (n+1)-th stages SRC2˜SRCn+1.

The gate signal GOUTk+1 of the (k+1)-th stage SRCk+1 or the vertical start signal STV is inputted to the second input terminal IN2 of the k-th stage SRCk. For example, the vertical start signal STV is inputted to the second input terminal IN2 of the final stage SRCn+1, and the (k+1)-th gate signal GOUTk+1 is inputted to the second input terminal IN2 of the first to n-th stages SRC1˜SRCn.

An off-voltage VOFF is inputted to the voltage terminal VSS of the k-th stage SRCk. A high value of the first clock signal CK or the second clock signal CKB provided to the first clock terminal CK1, is outputted to the first output terminal OUT and the second output terminal CR. In this exemplary embodiment, the signal outputted to the first output terminal OUT is defined as the k-th gate signal GOUTk, and the signal outputted to the second output terminal CR is defined as the k-th carry signal COUTk.

The line part LS is formed at one edge of the circuit part CS. The line part LS may include a start signal line SL1, a first clock line SL2, a second clock line SL3 and a voltage line SL4.

The start signal line SL1 receives the vertical start signal STV from an external device (not shown), to provide the vertical start signal STV to the first input terminal IN1 of the first stage SRC1 and the second input terminal IN2 of the final stage SRCn+1.

The first clock line SL2 and the second clock line SL3 respectively receive the first clock signal CK and the second clock signal CKB to provide the first and second clock signals CK and CKB to the first and second clock terminals CK1 and CK2.

The voltage line SL4 receives the off-voltage VOFF, to provide the off-voltage VOFF to the voltage terminal VSS of each stage SRC.

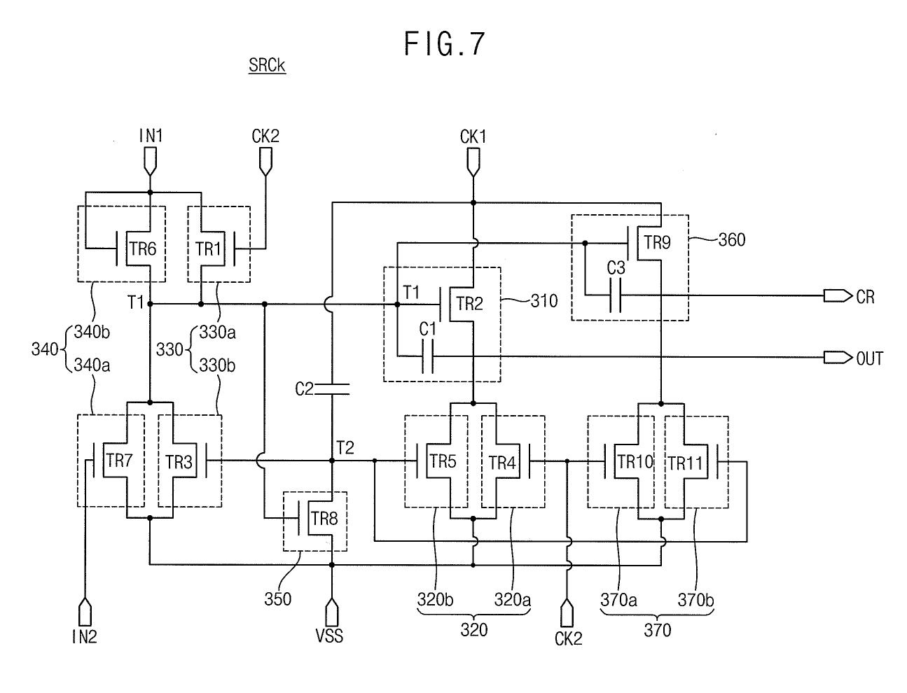

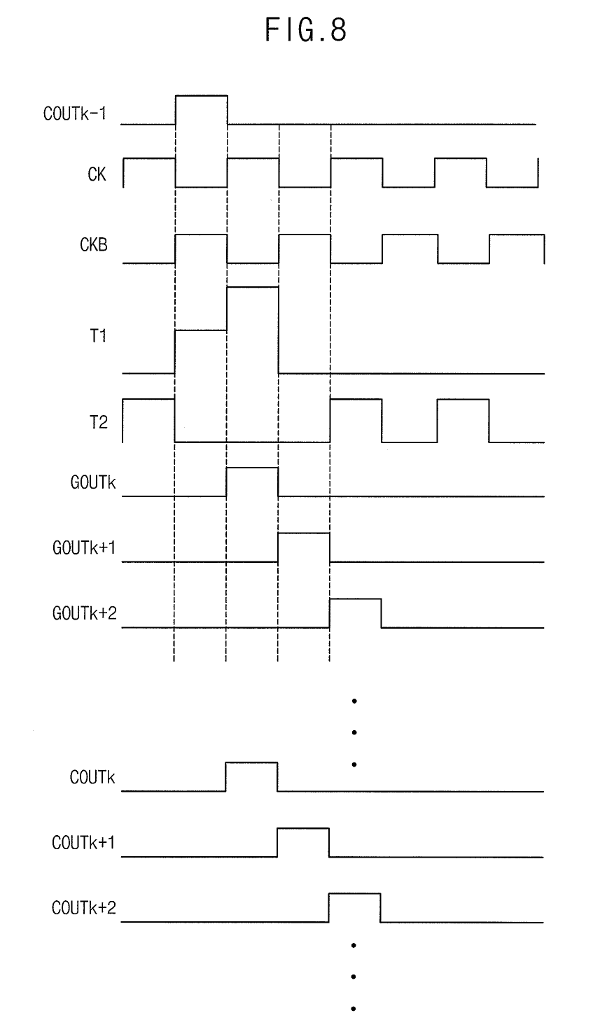

FIG. 7 is a circuit diagram illustrating a stage in FIG. 6. FIG. 8 is a waveform diagram illustrating a driving operation of the stage in FIG. 7.

For the convenience of explanation, the k-th stage SRCk, which is the odd-numbered stage that the first clock signal CK is provided to the first clock terminal CK1 and the second clock signal CKB is provided to the second clock terminal CK2, will be explained as an exemplary embodiment.

Referring to FIGS. 7 and 8, the k-th stage SRCk of the gate driving circuit 300 may include a pull-up part 310 and a pull-down part 320. The pull-up part 310 outputs the high value of the first clock signal CK to the first output terminal OUT to pull up the k-th gate signal GOUTk. The pull-down part 320 may include a first pull-down part 320a and a second pull-down part 320b that are sequentially operated. The first and second pull-down parts 320a and 320b convert the signal outputted to the first output terminal OUT to be the off-voltage VOFF to pull down the signal, respectively, in response to the second clock signal CKB and the first clock signal CK.

The pull-up part 310 may include a second switching element TR2 having an input electrode, an output electrode, and a control electrode. The input electrode is electrically connected to the first clock terminal CK1 to receive the first clock signal CK. The output electrode is electrically connected to the first output terminal OUT. The control electrode receives the first input signal. The first input signal is a (k−1)-th carry signal COUTk−1 of the (k−1)-th stage SRCk−1, and is the vertical start signal STV in the first stage SRC1. The pull-up part 310 may further include a charging capacitor C1.

The first pull-down part 320a may include a fourth switching element TR4, and the second pull-down part 320b may include a fifth switching element TR5.

The k-th stage SRCk may further include a pull-up driving part 340. The pull-up driving part 340 turns the pull-up part 310 on, in response to the high value of the first input signal, and turns off the pull-up part 310, in response to the high value of the second input signal. For the convenience of explanation, the first input signal is called the (k−1)-th carry signal COUTk−1 and the second input signal is called the (k+1)-th gate signal GOUTk+1.

The pull-up driving part 340 may include a first pull-up driving part 340a and a second pull-up driving part 340b.

The first pull-up driving part 340a may include a seventh switching element TR7 having an input electrode, an output electrode, and a control electrode. The input electrode is electrically connected to the voltage terminal VSS. The output electrode is electrically connected to the control electrode of the second switching element TR2 to become a first node T1. The control electrode is electrically connected to the second input terminal IN2. The second pull-up driving part 340b may include a sixth switching element TR6 having an input electrode, a control electrode, and an output electrode. The input and control electrodes are electrically connected to the first input terminal IN1 in common. The output electrode is electrically connected to the first node T1.

In the pull-up driving part 340, the sixth switching element TR6 is turned on in response to the high value of the (k−1)-th carry signal COUTk−1, and the high value of the (k−1)-th carry signal COUTk−1 is applied to the first node T1 to be charged to the charging capacitor C1. The first clock signal CK is reversed to have the high value, for the second switching element TR2 to be bootstrapped, so that the high value of the first clock signal CK is outputted to the first output terminal OUT. Then, when the seventh switching element TR7 is turned on in response to the (k+1)-th gate signal GOUTk+1, the charging capacitor C1 is discharged to be the off-voltage VOFF, so that the first node T1 is converted to a low value. Thus, the second switching element is turned off.

The k-th stage SRCk may further include a ripple prevention part 330. The ripple prevention part 330 maintains the first node T1 to be the low value, so that it prevents a ripple of the first node T1. The tipple prevention part 330 may include a first ripple prevention part 330a and a second ripple prevention part 330b. The first ripple prevention part 330a may include a first switching element TR1 having an input electrode, an output electrode, and a control electrode. The input electrode is electrically connected to the first input terminal IN1. The output electrode is electrically connected to the first node T1. The control electrode is electrically connected to the second clock terminal CK1. The second ripple prevention part 340b may include a third switching element TR3 having an input electrode, an output electrode, and a control electrode. The input and output electrodes are electrically connected to the voltage terminal VSS and the first node T2. The control electrode is electrically connected to a switching capacitor C2.

In the ripple prevention part 300, when the first switching element TR1 is turned on in response to the high value of the second clock signal CKB, the low value of the (k−1)-th carry signal COUTk−1 is applied to the first node T1. Thus, the first node T1 is maintained at the low value. In addition, when the third switching element TR3 is turned on in response to the high value of the first clock signal CK charged to the switching capacitor C2, the first node T1 is continuously maintained at the low value by the off-voltage VOFF. The first and third switching element TR1 and TR3 are sequentially turned oil every 1H period, to maintain the first node T1 at the low value. Thus, the ripple generated at the first node T1 due to a coupling of the first clock signal CK may be prevented.

The k-th stage SRCk may further include a carry part 360 and a carry down part 370. The carry part 360 outputs the high value of the first clock signal CK to the second output terminal CR, so the carry part 360 pulls up the k-th carry signal COUTk. The carry down part 370 may include a first carry down part 370a and a second carry down part 370b. The first carry down part 370a converts the signal outputted to the second output terminal CR into the off-voltage VOFF (low value), in response to the high value of the second clock signal CKB, so that it pulls down the k-th carry signal COUTk. The second carry down part 370b maintains the signal outputted to the second output terminal CR to be the low value, in response to the first clock signal CK, so that it pulls down the k-th carry signal COUTk.

The carry part 360 may include a ninth switching element TR9 having an input electrode, an output electrode, and a control electrode. The input electrode is electrically connected to the first clock terminal CK1 to receive the first clock signal CK. The output electrode is electrically connected to the second output terminal CR. The control electrode receives the (k−1)-th carry signal COUTk−1. The carry part 360 may further include a carry capacitor C3 that is formed between the control and output electrodes of the ninth switching element TR9. The carry capacitor C3 stores the (k−1)-th carry signal COUTk−1 inputted to the control electrode of the ninth switching element TR9 to turn the ninth switching element TR9 on.

The first carry down part 370a may include a tenth switching element TR10 having an input electrode, a control electrode, and an output electrode. The input electrode is electrically connected to the voltage terminal VSS, to receive the off-voltage VOFF. The control electrode is electrically connected to the second clock terminal CK2, to receive the second clock signal CKB. The output electrode is electrically connected to the second output terminal CR. The second carry down part 370b may include an eleventh switching element TR11 having an input electrode, a control electrode, and an output electrode. The input electrode is electrically connected to the voltage terminal VSS to receive the off-voltage VOFF. The control electrode is electrically connected to the switching capacitor C2 to receive the first clock signal CK. The output electrode is electrically connected to the second output terminal CR. For example, the tenth and eleventh switching elements TR10 and TR11 are sequentially turned on, to pull down the signal outputted to the second output terminal CR to the off-voltage VOFF (low value).

The k-th stage SRCk may further include the switching capacitor C2 and a pull-down control part 350. The switching capacitor C2 transfers the first clock signal CK to turn on the second ripple prevention part 330b, the second pull-down part 320b and the second carry down part 370b. The pull-down control part 350 may include an eighth switching element TR8. The pull-down control part 350 turns off the second ripple prevention part 330b, the second pull-down part 320b, and the second carry down part 370b, in response to the first node T1 signal.

In the gate driving circuit 300 according to the exemplary embodiment, the first ripple prevention part 330a and the second ripple prevention part 330b maintain the low value of the first node T1, respectively, in response to the second clock signal CKB and the first clock signal CK. Thus, the ripple may be prevented.

According to an exemplary embodiment of the present invention, the gate driving circuit may include the first ripple prevention part and the second ripple prevent part to prevent the ripple generated at the control electrode of the pull-up part, so that the low value is safely maintained. Thus, noise malfunction in the gate signal due to ripple may be reduced. In addition, improvement of the gate signal malfunction increases pixel charging time of the data signal, so that driving malfunction of the display apparatus due to the increase of the driving frequency may be enhanced.

Having described exemplary embodiments of the present invention and the attendant advantages, it is noted that various changes, substitutions and alterations can be made herein without departing from the spirit and scope of the invention as defined by appended claims.

What is claimed is:

1. A gate driving circuit comprising a shift resister having a plurality of stages cascade-connected to one another,
each of the stages comprising:
a pull-up part outputting a high value of a first clock signal to a first output terminal, in response to a high value of a first input signal;
a first pull-up driving part applying a low value to a control electrode of the pull-up part, in response to a high value of a second input signal, to turn off the pull-up part;
a first pull-down part applying the low value to the signal outputted to the first output terminal, in response to a high value of a second clock signal; and
a first ripple prevention part applying the low value of the first input signal to the control electrode of the pull-up part in response to the high value of the second clock signal to turn off the pull-up part, and preventing ripple from occurring at the control electrode of the pull-up part.

2. The gate driving circuit of claim 1, wherein the first clock signal and the second clock signal are reversed by every 1H, where H is a horizontal section, period, and have respective phases reversed relative to each other.

3. The gate driving circuit of claim 2, wherein each of the stages further comprises a first clock terminal and a second clock terminal, and the first clock signal and the second clock signal are respectively inputted to the first and second clock terminals of odd-numbered stages, and to the second and first clock terminals of even-numbered stages.

4. The gate driving circuit of claim 2, wherein the first ripple prevention part comprises:
an input electrode electrically connected to a first input terminal, for receiving the first input signal;
a control electrode electrically connected to a second clock terminal, for receiving the second clock signal; and
an output electrode including a first switching element that is electrically connected to the control electrode of the pull-up part.

5. The gate driving circuit of claim 4, wherein the pull-up part comprises:
a second switching element having an input electrode, a control electrode and an output electrode, the input electrode being electrically connected to a first clock terminal for receiving the first clock signal, the control electrode receiving the first input signal, the output electrode electrically connected to the first output terminal; and
a charge capacitor formed between the control electrode and the output electrode of the second switching element, for storing the high value of the first input signal, to turn the second switching element on.

6. The gate driving circuit of claim 5, further comprising:
a switching capacitor receiving the first clock signal and being charged by the first clock signal;
a second pull-down part maintaining the signal outputted to the first output terminal to be in the low value, in response to the first clock signal charged to the switching capacitor;
a second ripple prevention part maintaining the control electrode of the pull-up part to be in the low value, in response to the first clock signal charged to the switching capacitor.

7. The gate driving circuit of claim 6, further comprising:
a second pull-up part receiving the first input signal through both an input electrode and a control electrode of the second pull-up part, and outputting the high value of the first input signal to the control electrode of the pull-up part; and
a pull-down control part turning off the second pull-down part and the second ripple prevention part, in response to the signal of the control electrode of the pull-up part.

8. The gate driving circuit of claim 7, wherein the first input signal in a k-th stage is the signal outputted to the first output terminal in a (k−1)-th stage, and the second input signal is the signal outputted to the first output terminal in a (k+1)-th stage, wherein k is a natural number.

9. The gate driving circuit of claim 8, wherein the first input signal in a first stage and the second input signal in a final stage are vertical start signals.

10. The gate driving circuit of claim 7, further comprising a cany part outputting the high value of the first clock signal to a second output terminal, in response to the high value of the first input signal.

11. The gate driving circuit of claim 10, further comprising:
a first carry down part applying the low value to the signal outputted to the second output terminal, in response to the high value of the second clock signal; and
a second carry down part applying the low value to the signal outputted to the second output terminal, in response to the first clock signal charged to the switching capacitor,
wherein the second carry down part is turned off by the pull-down control part.

12. The gate driving circuit of claim 11, wherein the first input signal in a k-th stage is the signal outputted to the second output terminal in a (k−1)-th stage, and the second input signal is the signal outputted to the first output terminal in a (k+1)-th stage, wherein k is a natural number.

13. The gate driving circuit of claim 12, wherein the first input signal in a first stage and the second input signal in a final stage are vertical start signals.

14. A display apparatus comprising:
a display panel including a display area having a plurality of pixel portions defined by gate lines and data lines, and a peripheral area disposed to enclose the display area;
a data driving circuit outputting a data signal to the data lines; and
a gate driving circuit formed in the peripheral area and including a plurality of stages cascade-connected to one another, for outputting a gate signal to the gate lines, each of tie stages of the gate driving circuit including:
a pull-up part outputting a high value of a first clock signal to a first output terminal, in response to a high value of a first input signal;
a first pull-up driving part applying a low value to a control electrode of the pull-up part, in response to a high value of a second input signal;
a first pull-down part applying the low value to the signal outputted to the first output terminal, in response to a high value of a second clock signal; and
a first ripple prevention part applying the low value of the first input signal to the control electrode of the pull-up part in response to the high value of the second clock signal to turn off the pull-up part, and preventing ripple from occurring at the control electrode of the pull-up part.

15. The display apparatus of claim 14, wherein the first clock signal and the second clock signal are reversed every 1H, where H is a horizontal section, period, and have respective phases reversed relative to each other.

16. The display apparatus of claim 15, wherein the first ripple prevention part comprises:
an input electrode electrically connected to a first input terminal, for receiving the first input signal;
a control electrode electrically connected to a second clock terminal, for receiving the second clock signal; and
an output electrode including a first switching element that is electrically connected to the control electrode of the pull-up part.

17. The display apparatus of claim 15, wherein the pull-up part comprises:
a second switching element having an input electrode, a control electrode and an output electrode, the input electrode being electrically connected to a first clock terminal for receiving the first clock signal, the control electrode receiving the first input signal, the output electrode electrically connected to the first output terminal; and
a charge capacitor, being formed between the control electrode and the output electrode of the second switching element, for storing the high value of the first input signal, to turn on the second switching element.

18. The display apparatus of claim 17, wherein each of the stages of the gate driving circuit comprises:
a switching capacitor receiving the first clock signal, to be charged by the first clock signal;
a second pull-down part maintaining the signal outputted to the first output terminal to be in the low value, in response to the first clock signal charged to the is switching capacitor;
a second ripple prevention part maintaining the control electrode of the pull-up part to be in the low value, in response to the first clock signal charged to the switching capacitor.

19. The display apparatus of claim 18, wherein each of the stages of the gate driving circuit comprises:
a second pull-up part receiving the first input signal through both an input electrode and a control electrode of the second pull-up part, and outputting the high value of the first input signal to the control electrode of the pull-up part; and
a pull-down control part turning off the second pull-down part and the second ripple prevention part, in response to the signal of the control electrode of the pull-up part.

20. The display apparatus of claim 19, wherein the first input signal in a k-th stage is the signal outputted to the first output terminal in a (k−1)-th stage, the second input signal is the signal outputted to the first output terminal in a (k+1)-th stage, wherein k is a natural number, and the first input signal in a first stage and the second input signal in a final stage are vertical start signals.

21. The display apparatus of claim 19, wherein each of the stages of the gate driving circuit includes a carry part, and the carry part outputs the high value of the first clock signal to a second output terminal, in response to the high value of the first input signal.

22. The display apparatus of claim 21, wherein each of the stages of the gate driving circuit comprises:
a first carry down part applying the low value to the signal outputted to the second output terminal, in response to the high value of the second clock signal; and
a second carry down part applying the low value to the signal outputted to the second output terminal, in response to the first clock signal charged to the switching capacitor,
wherein the second carry down part is turned off by the pull-down control part.

23. The display apparatus of claim 22, wherein the first input signal in a k-th stage is the signal outputted to the second output terminal in a (k−1)-th stage, the second input signal is the signal outputted to the first output terminal in a (k+1)-th stage, k is a natural number, and the first input signal in a first stage and the second input signal in a final stage are vertical start signals.
